(19) United States
(12) Patent Application Publication
(10) Pub. No.: US 2026/0231330 A1
(43) Pub. Date: Aug. 6, 2026

(54) COMPOSITE ELECTRONIC COMPONENT

(71) Applicant: TDK CORPORATION, Tokyo (JP)

(72) Inventors: Kazutoshi TSUYUTANI, Tokyo (JP); Toshiyuki ABE, Tokyo (JP)

(21) Appl. No.: 19/151,206

(22) PCT Filed: Jan. 23, 2024
(86) PCT No.: PCT/JP2024/001799

§ 371 Date: Jul. 25, 2025

(30) Foreign Application Priority Data
Feb. 16, 2023 (JP) 2023-022439

(51) Int. Cl. H05K 1/16; H05K 1/02; H05K 1/03; H05K 3/46

(52) U.S. Cl. CPC H05K 1/165; H05K 1/0259; H05K 1/0271; H05K 1/038; H05K 3/4644; H05K 3/4697; H05K 2201/068

(57) ABSTRACT

To improve, in a composite electronic component having a structure in which an electronic component is embedded in an insulating layer, the reliability of a conductor pattern using an insulating film provided on the outermost surface of the composite electronic component. A composite electronic component includes an insulating layer in which an ESD protection component is embedded; a wiring structure stacked on the insulating layer; and a solder resist covering a surface of the wiring structure. The solder resist covers an outer peripheral area, which is a part of the upper surface of the conductor pattern other than an area, on the upper surface of a conductor pattern and is filled in a clearance formed between an outer peripheral area defined on the lower surface of the conductor pattern and the surface.

### TECHNICAL FIELD

The present disclosure relates to a composite electronic component and, more particularly, to a composite electronic component having an insulating layer in which an electronic component is embedded and a wiring structure covering the insulating layer.

### BACKGROUND ART

Patent Document 1 discloses a printed wiring board having a structure in which an electronic component is embedded in an insulating layer.

### CITATION LIST

### Patent Document

[Patent Document 1] JP 2015-226013A

### DISCLOSURE OF THE INVENTION

### Problem to be Solved by the Invention

The outermost surface of the printed wiring board described in Patent Document 1 is covered with insulating film such as a solder resist.

The present disclosure relates to a composite electronic component having a structure in which an electronic component is embedded in an insulating layer and describes a technology capable of improving the reliability of a conductor pattern using an insulating layer provided on the outermost surface of the composite electronic component.

### Means for Solving the Problem

A composite electronic component according to an aspect of the present disclosure includes: a first insulating layer; an electronic component embedded in the first insulating layer; a wiring structure having first and second surfaces positioned opposite to each other and stacked on the first insulating layer such that the first surface and the first insulating layer face each other; a second insulating layer covering the second surface; and an external terminal. The wiring structure has a conductor pattern provided on the second surface. The second insulating layer covers the outer peripheral area of the conductor pattern, excluding part of the upper surface of the conductor pattern and is filled in a clearance formed between the outer peripheral area defined on the lower surface of the conductor pattern and the second surface.

### Advantageous Effects of the Invention

According to the present disclosure, a reliability of a conductor pattern can be improved by using an insulating layer provided on the outermost surface in a composite electronic component having a structure in which an electronic component is embedded in an insulating layer.

### BRIEF DESCRIPTION OF THE DRAWINGS

FIG. 1 is a schematic perspective view illustrating the outer appearance of a composite electronic component 1 according to an embodiment of the technology described herein.

FIG. 2 is a schematic cross-sectional view of the composite electronic component 1.

FIG. 3 is an enlarged view of the area A illustrated in FIG. 2.

FIG. 4 is an exploded perspective view of the composite electronic component 1.

FIG. 5 is a schematic plan view illustrating the shapes of the conductor patterns provided in the conductor layer C4.

FIG. 6 is a schematic plan view illustrating the shapes of the conductor patterns provided in the conductor layer C3.

FIG. 7 is a schematic plan view illustrating the shapes of the conductor patterns provided in the conductor layer C2.

FIG. 8 is a schematic plan view of the layer in which the ESD protection component 2 is embedded.

FIG. 9 is a schematic plan view illustrating the shapes of the conductor patterns provided in the conductor layer C1.

FIG. 10 is a schematic plan view illustrating the shapes of the conductor patterns provided in the conductor layer C0.

FIG. 11 is an equivalent circuit diagram of the composite electronic component 1.

FIG. 12 is a process view for explaining the manufacturing method for composite electronic component 1.

FIG. 13 is a process view for explaining the manufacturing method for composite electronic component 1.

FIG. 14 is a process view for explaining the manufacturing method for composite electronic component 1.

FIG. 15 is a process view for explaining the manufacturing method for composite electronic component 1.

FIG. 16 is a process view for explaining the manufacturing method for composite electronic component 1.

FIG. 17 is a process view for explaining the manufacturing method for composite electronic component 1.

FIG. 18 is a process view for explaining the manufacturing method for composite electronic component 1.

FIG. 19 is a process view for explaining the manufacturing method for composite electronic component 1.

FIG. 20 is a process view for explaining the manufacturing method for composite electronic component 1.

FIG. 21 is a process view for explaining the manufacturing method for composite electronic component 1.

FIG. 22 is a process view for explaining the manufacturing method for composite electronic component 1.

FIG. 23 is a process view for explaining the manufacturing method for composite electronic component 1.

FIG. 24 is a schematic cross-sectional view of the composite electronic component according to a modification.

FIGS. 25(a) and 25(b) are enlarged views of the area A illustrated in FIG. 24.

### MODE FOR CARRYING OUT THE INVENTION

Hereinafter, some embodiments of the present invention will be described in detail with reference to the accompanying drawings.

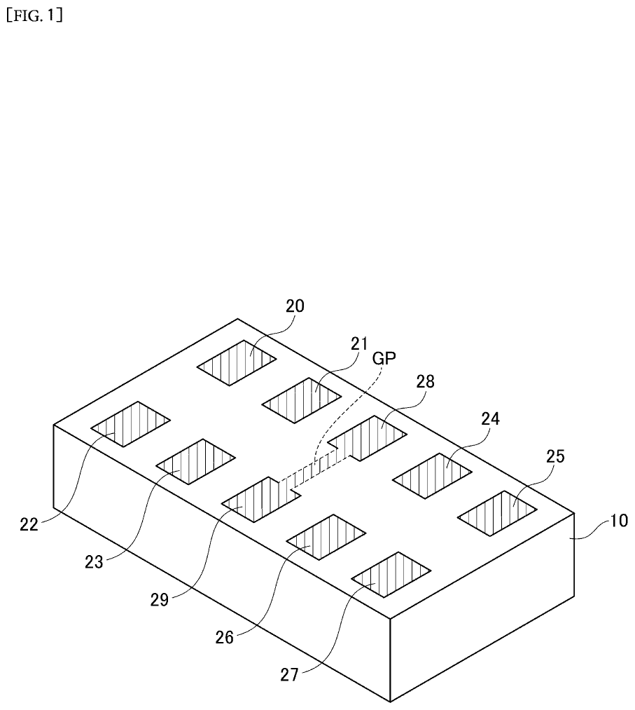

FIG. 1 is a schematic perspective view illustrating the outer appearance of a composite electronic component 1 according to an embodiment of the technology described herein.

The composite electronic component 1 according to the present embodiment is a surface-mounted chip component and has, as illustrated in FIG. 1, an element body 10 and a plurality of external terminals arranged in an array on the surface of the element body 10. The plurality of external terminals includes eight signal terminals 20 to 27 and two ground terminals 28 and 29. The composite electronic component 1 may be configured such that the signal terminals 20 to 27 and ground terminals 28 and 29 are not provided, but instead part of conductor patterns 50 to 59 to be described later are used as external terminals.

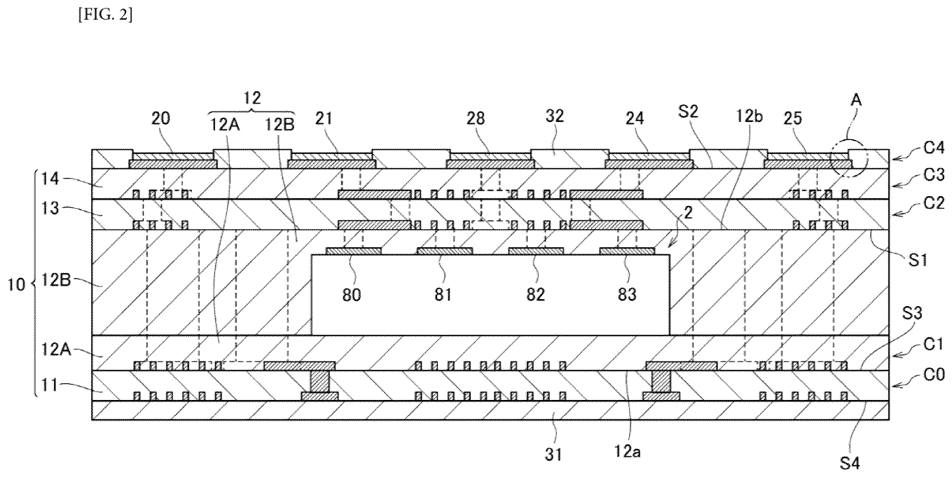

FIG. 2 is a schematic cross-sectional view of the composite electronic component 1.

As illustrated in FIG. 2, the element body 10 has a structure in which insulating layers 11 to 14 made of resin or the like are stacked in this order. The insulating layer 11 is provided on one surface side (surface 12a side) of the insulating layer 12, and the insulating layers 13 and 14 are provided on the other surface side (surface 12b side) of the insulating layer 12. A conductor layer C1 is formed between the surface 12a of the insulating layer 12 and the insulating layer 11. A conductor layer C0 is formed on the surface of the insulating layer 11. The conductor layer C0 is covered with a solder resist 31. The insulating layer 11 and the conductor layers C0 and C1 formed on both surfaces of the insulating layer 11 constitute a first wiring structure. The first wiring structure has a surface S3 constituted by the upper surface of the insulating layer 11 and a surface S4 constituted by the lower surface of the insulating layer 11 and is stacked on the insulating layer 12 such that the surface S3 faces the surface 12a of the insulating layer 12. The conductor layers C0 and C1 are embedded respectively in the insulating layers 11 and 12. As a result, the flatness of the outermost surface of the first wiring structure becomes higher than when the conductor layer C0 is provided so as to protrude from the surface of the insulating layer 11, thus making it possible to ensure sufficient insulation performance even when the thickness of the solder resist 31 is reduced. Although one insulating layer 11 is included in the first wiring structure in the example illustrated in FIG. 2, the number of layers of the insulating layers included in the first wiring structure is not particularly limited. Further, using a core material obtained by impregnating a core such as glass cloth with a resin as the insulating layer 11 can enhance rigidity and reduce coefficient of thermal expansion.

A conductor layer C2 is formed between the surface 12b of the insulating layer 12 and the insulating layer 13. The conductor layer C2 is covered with the insulating layer 13. A conductor layer C3 is formed on the surface of the insulating layer 13. The conductor layer C3 is covered with the insulating layer 14. A conductor layer C4 is formed on the surface of the insulating layer 14. The conductor layer C4 is covered with a solder resist 32. The insulating layers 13 and 14 and the conductor layers C2 to C4 formed on both surfaces of each of the insulating layers 13 and 14 constitute a second wiring structure. The second wiring structure has a surface S1 constituted by the lower surface of the insulating layer 13 and a surface S2 constituted by the upper surface of the insulating layer 14 and stacked on the insulating layer 12 such that the surface S1 faces the surface 12b of the insulating layer 12. The conductor layers C2 and C3 are embedded respectively in the insulating layers 13 and 14. On the other hand, the conductor layer C4 protrudes from the surface of the insulating layer 14. Although two insulating layers 13 and 14 are included in the second wiring structure in the example illustrated in FIG. 2, the number of layers of the insulating layers included in the second wiring structure is not particularly limited. Further, using a core material obtained by impregnating a core such as glass cloth with a resin as the insulating layers 13 and 14 can enhance rigidity and reduce coefficient of thermal expansion.

The insulating layers 11 to 14 are each an interlayer film having conductor layers on its front and back, while the solder resists 31 and 32 are insulating layers each covering the outermost surface of the wiring structure. In the example illustrated in FIG. 2, the solder resist 31 covers the entire outermost surface of the insulating layer 11. Thus, in this example, the conductor layer C0 is not exposed but is covered with the solder resist 31. On the other hand, the solder resist 32 partially has openings, and a part of the conductor layer C4 that is exposed from each of the openings is used as the external terminal.

Conductor patterns 50 to 59 to be described later may be included in the conductor layer C4, and a part of each thereof may be used as the external terminal. Alternatively, as illustrated in FIGS. 1 and 2, the signal terminals 20 to 27 and ground terminals 28 and 29 may each be used as the external terminal. The signal terminals 20 to 27 and ground terminals 28 and 29 may each be a plated layer formed by, for example, nickel/gold (Ni/Au) plating, nickel/palladium/gold (Ni/Pa/Au) plating, or the like, may be a film formed by surface treatment such as water-soluble preflux (OSP), may be a solder bump formed by soldering, may be a copper bump formed using copper, or may be a gold bump formed using gold (Au). The signal terminals 20 to 27 and ground terminals 28 and 29 are not particularly limited in shape and may be adjusted in shape depending material, formation process, and purpose.

The insulating layer 12 includes insulating layers 12A and 12B stacked one on the other, and an ESD protection component 2 is embedded in the insulating layer 12. The ESD protection component 2 is constituted by a semiconductor substrate and thus differs in coefficient of thermal expansion from the insulating layers 11 to 14. However, in the present embodiment, the ESD protection component 2 is positioned at substantially the center in the stacking direction, and the insulating layers 11, 13, and 14 are provided on both sides of the ESD protection component 2, so that the degree of freedom when the symmetry in the stacking direction is adjusted by adjusting the thickness is high, thus making it unlikely to cause warpage of the entire composite electronic component 1 due to temperature change. As the insulating layer 12, a resin material not containing a core material such as glass cloth is preferably used so as not to inhibit embedding of the ESD protection component 2.

FIG. 3 is an enlarged view of the area A illustrated in FIG. 2.

A conductor pattern 55 included in the conductor layer C4 is provided on the surface S2 constituted by the surface of the insulating layer 14. The upper surface of the conductor pattern 55 has an area Al which is not covered with the solder resist 32 but on which the signal terminal 25 is directly formed and an outer peripheral area A2 covered with the solder resist 32. The lower surface of the conductor pattern 55 has an area A3 contacting the surface S2 and an outer peripheral area A4 not contacting the surface S2 but forming a clearance B. The area Al (and A3) is not particularly limited in position, shape, and size. The area Al may be formed into, for example, a circular shape, an elliptic shape, a substantially rectangular shape, and the like including the center of the conductor pattern 55. The area Al may be formed, for example, at an area (center area) including the center of the conductor pattern 55. The center position of the area Al may coincide with or differ from, for example, the center position of the conductor pattern 55. The outer peripheral areas A2 and A4 are not particularly limited in shape or size. The clearance B formed by the outer peripheral area A4 is filled with the solder resist 32, whereby the outer peripheral portion of the conductor pattern 55 is vertically sandwiched by the solder resist 32. This enhances adhesion between the conductor pattern 55 and the solder resist 32, making it unlikely to cause peeling of the solder resist 32. Further, since the conductor pattern 55 is sandwiched by the solder resist 32, adhesion between the conductor pattern 55 and the surface S2 is enhanced. Thus, the amount of roughening of the surface of the conductor pattern 55 that contacts the surface S2 can be reduced more than when the solder resist 32 is absent, thereby making it possible to reduce an electrical resistance.

A width W2 of the outer peripheral area A2 defined on the upper surface of the conductor pattern 55 and covered with the solder resist 32 is larger than a width W4 of the outer peripheral area A4 defined on the lower surface of the conductor pattern 55 and covered with the solder resist 32. This can ensure sufficient adhesion between the conductor pattern 55 and the surface S2 of the insulating layer 14. Further, a displacement corresponding to (W2-W4) cours between the planar position of the end portion of the solder resist 32 covering the outer peripheral area A2 and the planar position of the end portion of the solder resist 32 covering the outer peripheral area A4, so that stress applied to the conductor pattern 55 through the solder resist 32 is distributed to reduce damage to the conductor pattern 55.

In the present embodiment, the insulating layer 12 does not contain a core material such as glass cloth, so that it has a high coefficient of thermal expansion and is likely to be deformed. However, the insulating layers 11, 13, and 14 constituting the first and second wiring structures contain a core material such as glass cloth and are thus lower in coefficient of thermal expansion than the insulating layer 12, SO that deformation of the insulating layer 12 can be suppressed by the presence of the insulating layers 11, 13, and 14. This reduces stress which is applied to the conductor pattern 55 due to a thermal change, thereby making unlikely to cause peeling at the interface between the conductor pattern 55 and the solder resist 32. In addition, as described above, the outer peripheral portion of the conductor pattern 55 is vertically sandwiched by the solder resist 32, so that it is possible to suppress peeling of the conductor pattern 55 from the insulating layer 14. This improves the connection reliability of the conductor pattern 55.

Further, to further reduce damage applied to the conductor pattern 55 due to a thermal change, the pattern thickness of the conductor layer C4 may be larger than the pattern thicknesses of the other conductor layers Cl to C3. In the example illustrated in FIG. 3, the area Al on the upper surface of the conductor pattern 55 is lower in position than the outer peripheral area A2. This is a result of etching for the conductor pattern 55 performed, as pre-processing, before formation of the signal terminal 25.

While the above description has been made focusing on the conductor pattern 55 serving as a base of the signal terminal 25, the same applies to bases of the other external terminals (that is, the conductor patterns of the other external terminals all have the clearance B filled with the solder resist 32).

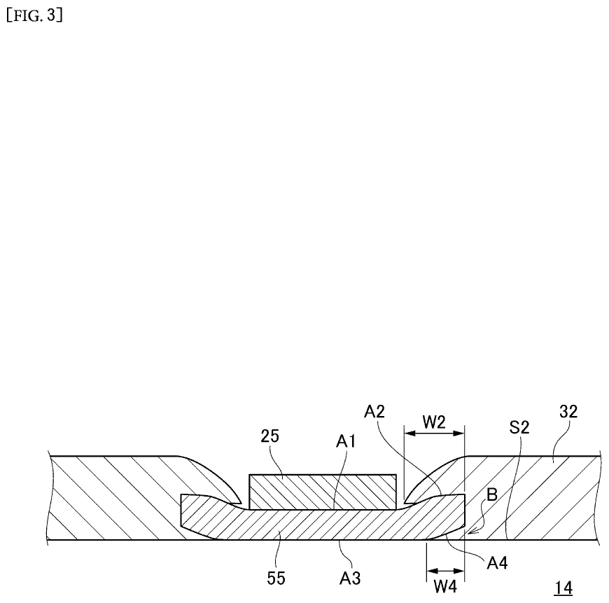

FIG. 4 is an exploded perspective view of the composite electronic component 1.

As illustrated in FIG. 4, coil patterns 41 to 48 are embedded in the composite electronic component 1. The coil patterns 41 and 42 are disposed in the conductor layer C3, coil patterns 43 and 44 are disposed in the conductor layer C2, coil patterns 45 and 46 are disposed in the conductor layer C1, and coil patterns 47 and 48 are disposed in the conductor layer C0. The coil patterns 41 and 43 overlap each other in a plan view through the insulating layer 13, and the coil patterns 42 and 44 overlap each other in a plan view through the insulating layer 13. The coil patterns 45 and 47 overlap each other in a plan view through the insulating layer 11, and coil patterns 46 and 48 overlap each other in a plan view through the insulating layer 11.

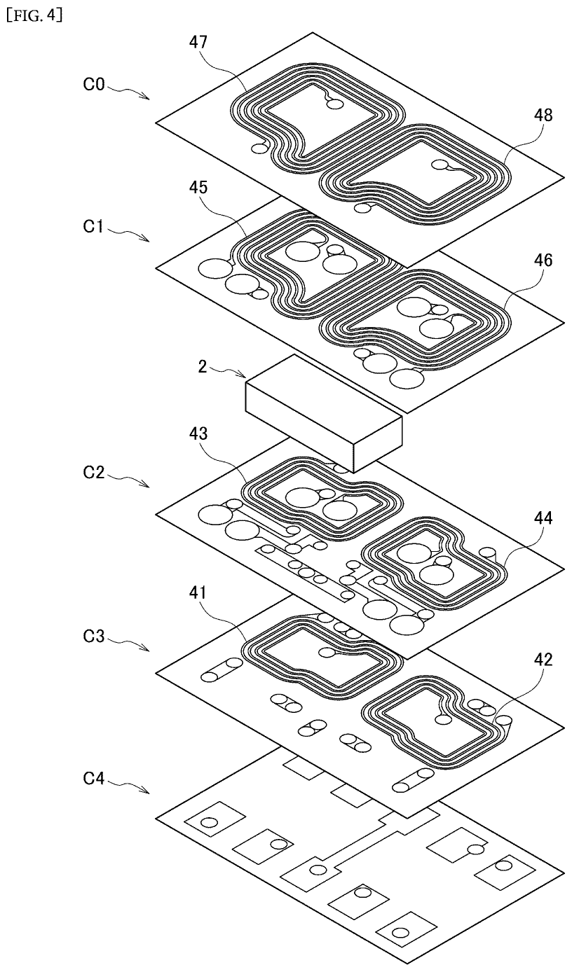

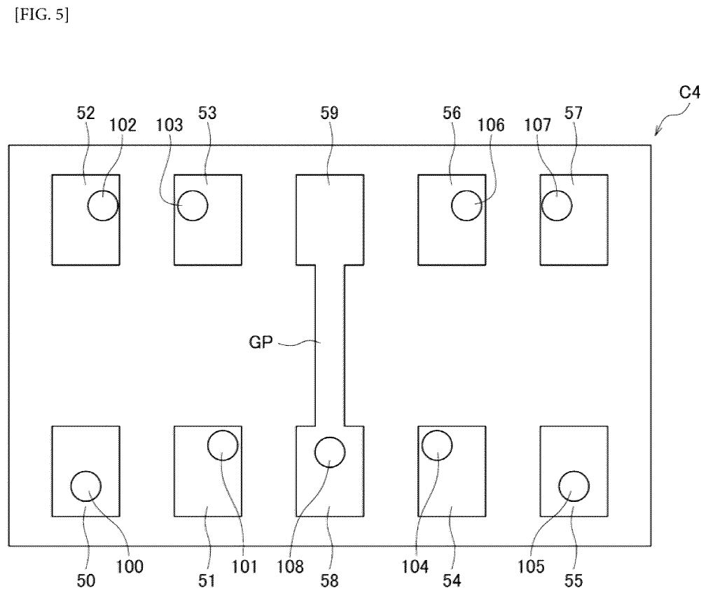

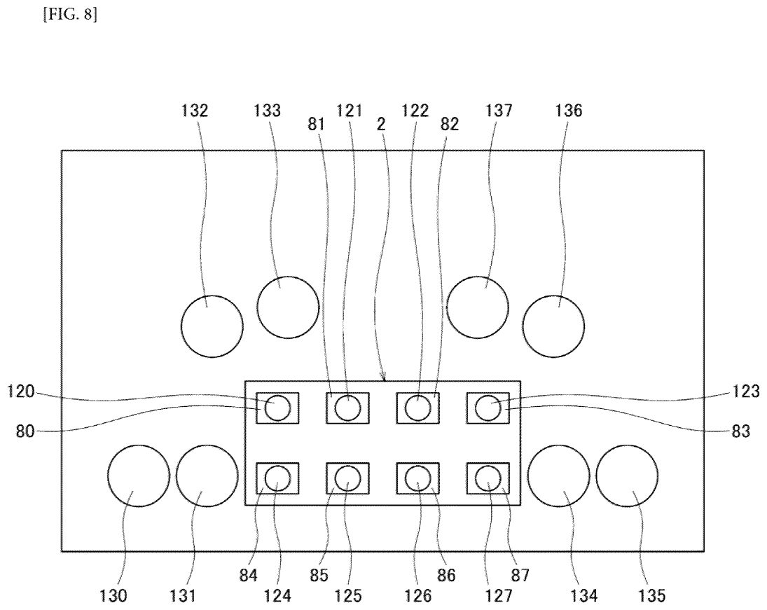

FIGS. 5 to 7, 9, and 10 are schematic plan views respectively illustrating the shapes of the conductor patterns provided in the conductor layers C4, C3, C2, C1, and C0. FIG. 8 is a schematic plan view of the layer in which the ESD protection component 2 is embedded.

As illustrated in FIG. 5, the conductor layer C4 has conductor patterns 50 to 59 and a ground pattern GP. The exposed parts of the conductor patterns 50 to 57 from the solder resist 32 are subjected to surface treatment and used as signal terminals 20 to 27, respectively. The exposed parts of the conductor patterns 58 and 59 from the solder resist 32 are subjected to surface treatment and used as ground terminals 28 and 29, respectively. The conductor patterns 58 and 59 are connected to each other through the ground pattern GP. The ground pattern GP is a linearly extending conductor pattern and has a width smaller than those of the conductor patterns 58 and 59. As described above, the ground pattern GP, signal terminals 20 to 27, and conductor patterns 58 and 59 are disposed in the same conductor layer (conductor layer C4), thus eliminating the need of providing an additional conductor layer for the ground pattern GP.

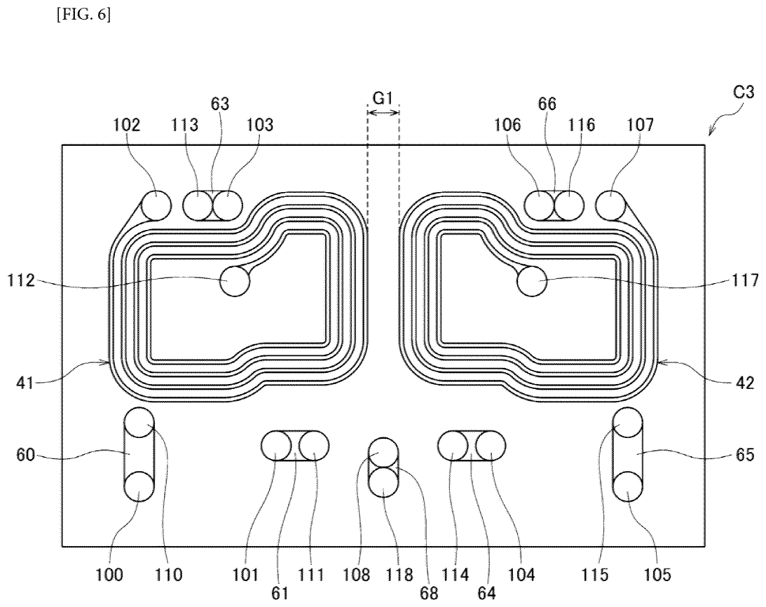

As illustrated in FIG. 6, the conductor layer C3 has the coil patterns 41 and 42 and conductor patterns 60, 61, and 63 to 66. The outer peripheral end of the coil pattern 41 is connected to the conductor pattern 52 through a via conductor 102. The outer peripheral end of the coil pattern 42 is connected to the conductor pattern 57 through a via conductor 107. The conductor patterns 60, 61, and 63 to 66 are connected respectively to the conductor patterns 50, 51, and 53 to 56 through respective via conductors 100, 101, and 103 to 106 formed in the insulating layer 14. The coil patterns 41 and 42 are disposed adjacent to each other with a gap G1 therebetween. In the conductor layer C3, a ground pattern and the like are not provided in the gap G1, and the coil patterns 41 and 42 are directly adjacent to each other through the insulating layer 14.

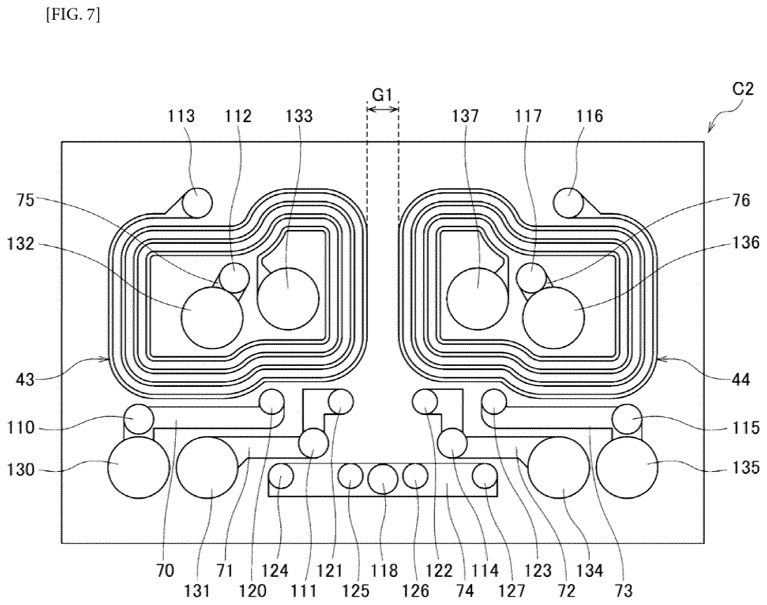

As illustrated in FIG. 7, the conductor layer C2 has the coil patterns 43 and 44 and conductor patterns 70 to 76. The outer peripheral end of the coil pattern 43 is connected to the conductor pattern 63 through a via conductor 113. The outer peripheral end of the coil pattern 44 is connected to the conductor pattern 66 through a via conductor 116. The conductor patterns 70 to 74 are connected respectively to the conductor patterns 60, 61, 64, 65, and 68 through respective via conductors 110, 111, 114, 115, and 118. The conductor patterns 75 and 76 are connected respectively to the inner peripheral ends of the coil patterns 41 and 42 through via conductors 112 and 117. The coil patterns 43 and 44 are disposed adjacent to each other with the gap G1 therebetween. In the conductor layer C2, a ground pattern and the like are not provided in the gap G1, and the coil patterns 43 and 44 are directly adjacent to each other through the insulating layer 13.

The coil patterns 41 to 44 each have a configuration in which the conductor patterns are wound in about four turns. The coil patterns 41 and 43 overlap each other in the stacking direction and substantially coincide with each other excluding the positions of the outer and inner peripheral ends. Similarly, the coil patterns 42 and 44 overlap each other in the stacking direction and substantially coincide with each other excluding the positions of the outer and inner peripheral ends. Further, in a plan view, the coil patterns 41 and 42 are symmetric to each other in terms of the pattern shape and, similarly, the coil patterns 43 and 44 are symmetric to each other in terms of the pattern shape.

As illustrated in FIG. 8, terminal electrodes 80 to 87 are provided on the surface of the ESD protection component 2. The terminal electrodes 80 to 83 are connected respectively to the conductor patterns 70 to 73 through respective via conductors 120 to 123 formed in the insulating layer 12. The terminal electrodes 84 to 87 are connected in common to the conductor pattern 74 through respective via conductors 124 to 127 formed in the insulating layer 12.

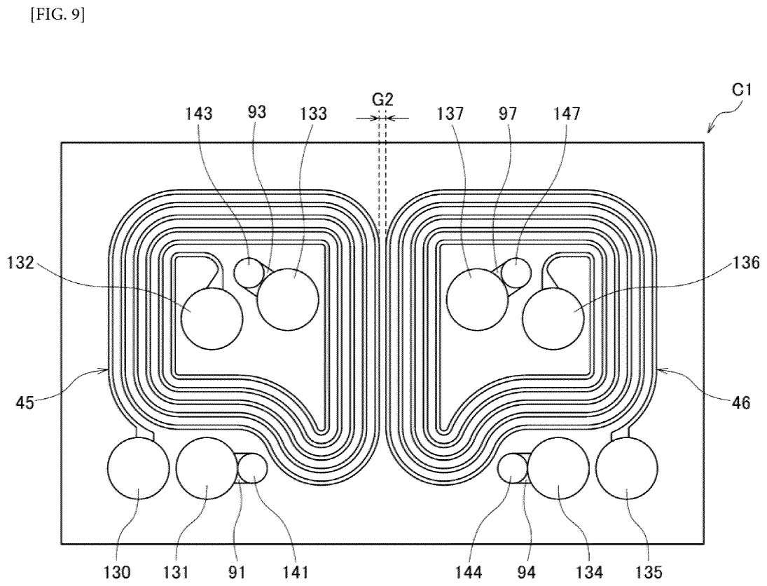

As illustrated in FIG. 9, the conductor layer Cl has the coil patterns 45 and 46 and conductor patterns 91, 93, 94, and 97. The outer peripheral end of the coil pattern 45 is connected to the conductor pattern 70 through a via conductor 130. The outer peripheral end of the coil pattern 46 is connected to the conductor pattern 73 through a via conductor 135. The inner peripheral end of the coil pattern 45 is connected to the conductor pattern 75 through a via conductor 132. The inner peripheral end of the coil pattern 46 is connected to the conductor pattern 76 through a via conductor 136. The conductor patterns 91 and 94 are connected respectively to the conductor patterns 71 and 72 through respective via conductors 131 and 134. The conductor patterns 93 and 97 are connected respectively to the inner peripheral ends of the coil patterns 43 and 44 through respective via conductors 133 and 137. The coil patterns 45 and 46 are disposed adjacent to each other with a gap G2 therebetween. In the conductor layer C1, a ground pattern and the like are not provided in the gap G2, and the coil patterns 45 and 46 are directly adjacent to each other through the insulating layer 12.

As illustrated in FIG. 10, the conductor layer C0 has the coil patterns 47 and 48. The outer and inner peripheral ends of the coil pattern 47 are connected respectively to the conductor patterns 91 and 93 through respective via conductors 141 and 143. The outer and inner peripheral ends of the coil pattern 48 are connected respectively to the conductor patterns 94 and 97 through respective via conductors 144 and 147. The coil patterns 47 and 48 are disposed adjacent to each other with the gap G2 therebetween. In the conductor layer C0, a ground pattern and the like are not provided in the gap G2, and the coil patterns 47 and 48 are directly adjacent to each other through the insulating layer 11.

The coil patterns 45 to 48 each have a configuration in which the conductor patterns are wound in about five turns. The coil patterns 45 and 47 overlap each other in the stacking direction and substantially coincide with each other excluding the positions of the outer and inner peripheral ends. Similarly, the coil patterns 46 and 48 overlap each other in the stacking direction and substantially coincide with each Other excluding the positions of the outer and inner peripheral ends. Further, in a plan view, the coil patterns 45 and 46 are symmetric to each other in terms of the pattern shape and, similarly, the coil patterns 47 and 48 are symmetric to each other in terms of the pattern shape.

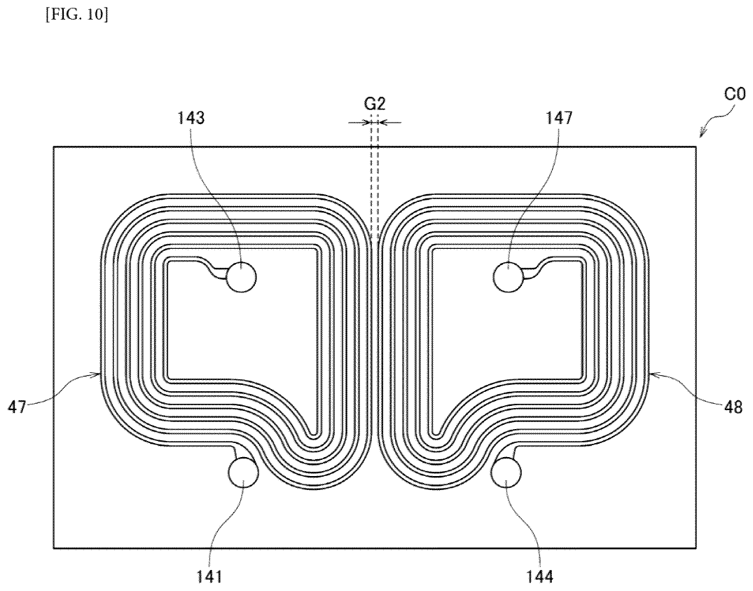

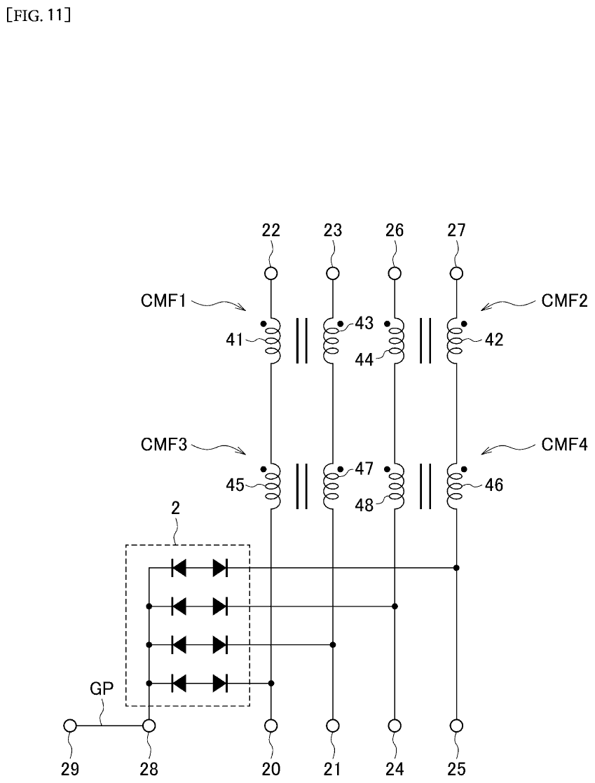

FIG. 11 is an equivalent circuit diagram of the composite electronic component 1 according to the present embodiment.

As illustrated in FIG. 11, in the composite electronic component 1 according to the present embodiment, the coil patterns 45 and 41 are connected in series between signal terminals 20 and 22, coil patterns 47 and 43 are connected in series between the signal terminals 21 and 23, coil patterns 48 and 44 are connected in series between the signal terminals 24 and 26, and coil patterns 46 and 42 are connected in series between the signal terminals 25 and 27. The coil patterns 41 and 43 are magnetically coupled to each other to constitute a common mode filter CMF1, coil patterns 42 and 44 are magnetically coupled to each other to constitute a common mode filter CMF2, coil patterns 45 and 47 are magnetically coupled to each other to constitute a common mode filter CMF3, and coil patterns 46 and 48 are magnetically coupled to each other to constitute a common mode filter CMF4. Further, protective elements integrated in the ESD protection component 2 are inserted between the signal terminals 20, 21, 24, 25 and the ground terminals 28, 29. As a result, the composite electronic component 1 according to the present embodiment constitutes a common mode filter array with ESD protective function. The ground terminal 29 is connected to the ESD protection component 2 through the ground pattern GP.

As described above, in the composite electronic component 1 incorporating the electronic component different in coefficient of thermal expansion from the substrate material, the outer peripheral portion of the conductor pattern serving as a base of the external terminal is vertically sandwiched by the solder resist 32, so that even when the insulating layer 12 having a high coefficient of thermal expansion is deformed, peeling of the external; terminal is suppressed. Further, peeling of the solder resist 32 is also unlikely to occur.

The following describes a manufacturing method for the composite electronic component 1 according to the present embodiment.

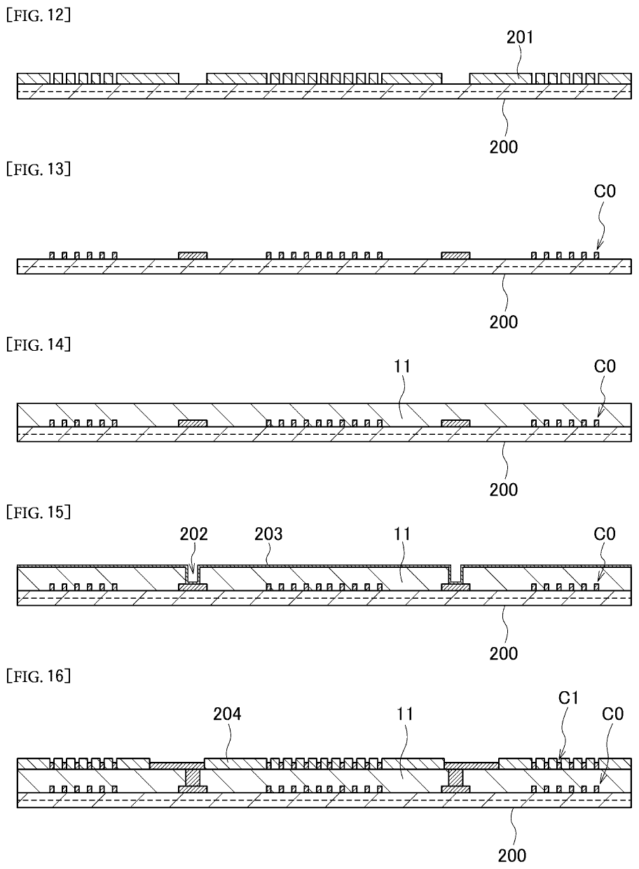

FIGS. 12 to 23 are process views for explaining the manufacturing method for composite electronic component 1 according to the present embodiment.

First, a carrier-attached copper foil 200 is prepared, and a resist pattern 201 is formed on the surface thereof (FIG. 12). The carrier-attached copper foil 200 has a structure in which a release layer is provided between two layers of copper foil. The resist pattern 201 is a negative pattern of the conductor layer C0. In this state, electrolytic plating is performed, followed by removal of the resist pattern 201, whereby the conductor layer C0 is formed (FIG. 13). Subsequently, the insulating layer 11 is formed on the surface of the carrier-attached copper foil 200 so as to embed therein the conductor layer Co (FIG. 14). As a result, the side and upper surfaces of the conductor pattern positioned in the conductor layer C0 are covered with the insulating layer 11.

Upon formation of the conductor layer C0, the surface roughness (roughness of the upper surface covered with the insulating layer) of the surface contacting the insulating layer 11 may be appropriately adjusted. For example, the adjustment of the surface roughness may be made by control of electrolytic plating conditions upon formation of the conductor layer C0, or by application of adequate surface treatment (blasting, etching, etc.) to the conductor layer C0.

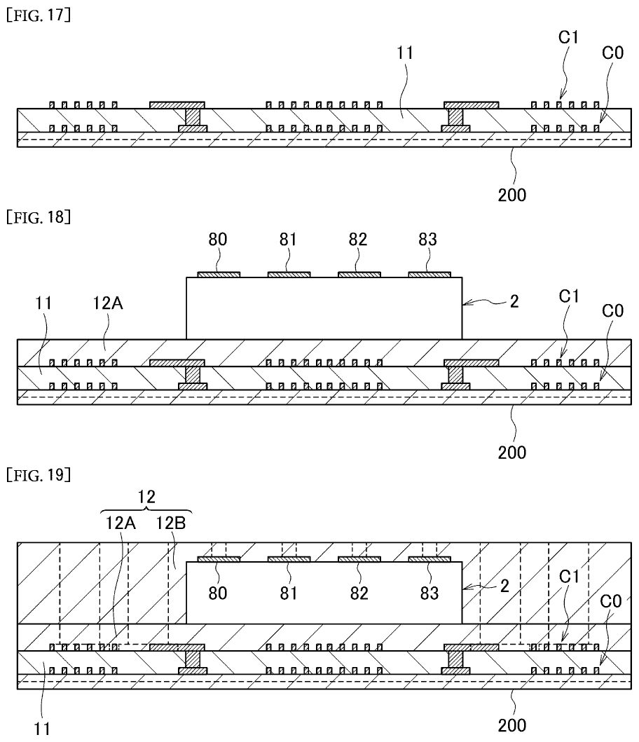

Then, a via 202 is formed at the formation position of a via conductor to expose a part of the conductor layer C0, and electroless plating is performed to form a seed layer 203 on the surface of the insulating layer 11 (FIG. 15). Subsequently, a resist pattern 204 is formed on the surface of the seed layer 203, and electrolytic plating is performed to form the conductor layer C1 (FIG. 16). Subsequently, after removal of the resist pattern 204 (FIG. 17), the insulating layer 12A is formed on the surface of the insulating layer 11 so as to embed therein the conductor layer C1, and the ESD protection component 2 is mounted on the surface of the insulating layer 12A (FIG. 18). As a result, the side and upper surfaces of the conductor pattern positioned in the conductor layer Cl are covered with the insulating layer 12A. Subsequently, the insulating layer 12B is formed on the surface of the insulating layer 12A so as to embed therein the ESD protection component 2 (FIG. 19). As a result, the ESD protection component 2 is embedded in the insulating layer 12 (12A, 12B).

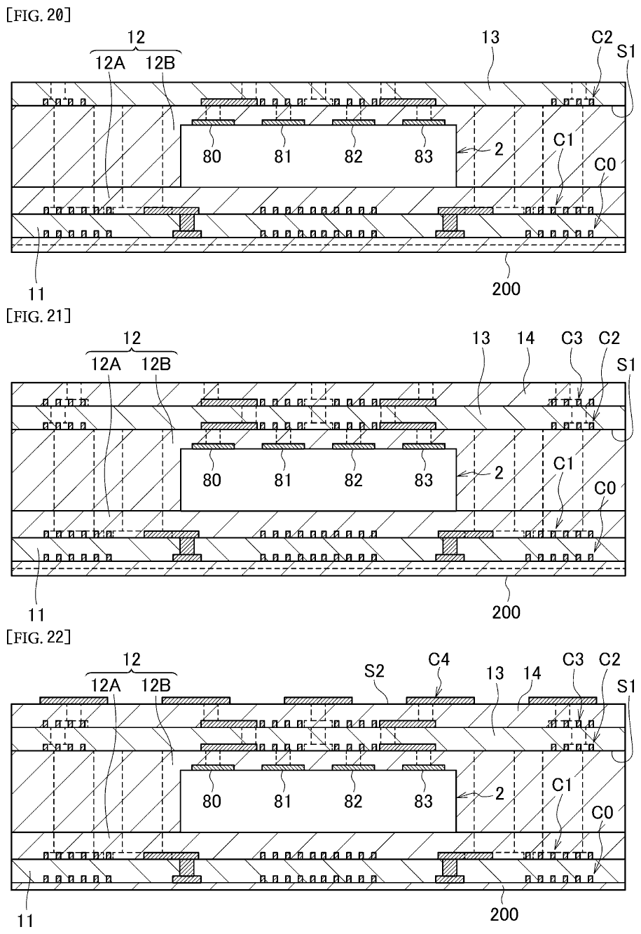

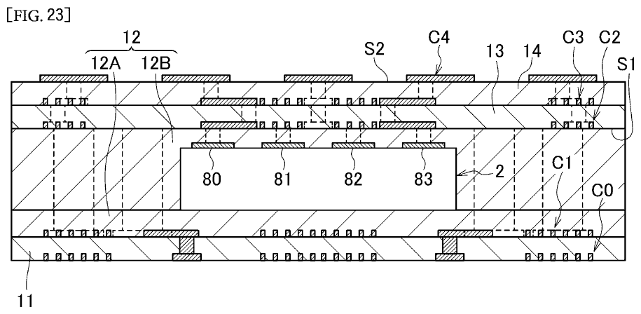

Then, the processes described using FIGS. 15 to 17 are repeated to form the conductor layer C2 on the surface of the insulating layer 12, and the insulating layer 13 is formed on the surface of the insulating layer 12 so as to embed therein the conductor layer C2 (FIG. 20). This process is repeated again to form the conductor layer C3 on the surface of the insulating layer 13, and the insulating layer 14 is formed on the surface of the insulating layer 13 so as to embed therein the conductor layer C3 (FIG. 21). Subsequently, after formation of the conductor layer C4 on the surface of the insulating layer 14, the copper foil is peeled by one layer through the release layer included in the carrier-attached copper foil 200 (FIG. 22), and the remaining layer of the copper foil is removed by etching (FIG. 23). Through this etching, the seed layer used for formation of the conductor layer C4 is also removed. At this time, the etching is performed under the condition that etching rate is higher for the seed layer formed by the electroless plating than for the conductor layer C4 formed by the electrolytic plating, followed by over-etching to form the clearance B described using FIG. 3. The width W4 of the clearance B can be adjusted by an over-etching time.

The surface roughness (surface roughness of the lower surface of the conductor layer C4 in the stacking direction) of the surface of the conductor layer C4 contacting the insulating layer 14 can be adjusted by, for example, control of the surface roughness of the insulating layer 14. For example, the adjustment of the surface roughness of the insulating layer 14 may be made by control of surface treatment (smoothing, polishing, etc.) carried out after formation of the insulating layer 14. As the conductor layer C4, a copper foil that has previously been roughened physically, chemically, or both physically and chemically may be used.

Further, the surface roughness of the lower surface (surface on which the carrier-attached copper foil 200 is provided) of the insulating layer 11 may be adjusted as needed. The adjustment of the surface roughness may be made by etching processing for the remaining copper foil of the carrier-attached copper foil 200 or subsequent various kinds of treatment (smoothing, polishing, etc.).

Then, the solder resists 31 and 32 are formed respectively on the outermost surfaces of the insulating layers 11 and 14, and the signal terminals 21 to 27 and ground terminals 28 and 29 are formed through surface treatment. At this time, the solder resist 32 is formed under the condition that the solder resist 32 enters the clearance B. Thus, the composite electronic component 1 according to the present embodiment is completed.

As described above, in the manufacturing process of the composite electronic component 1 according to the present embodiment, the etching is performed under the condition that etching rate is higher for the seed layer formed by the electroless plating than for the conductor layer C4 formed by the electrolytic plating, thus allowing the clearance B to be formed at the outer peripheral area of the lower surface of the conductor layer C4.

While the preferred embodiment of the present disclosure has been described, the present disclosure is not limited to the above embodiment, and various modifications may be made within the scope of the present disclosure, and all such modifications are included in the present disclosure.

For example, although the ESD protection component 2 is embedded in the insulating layer 12 in the above embodiment, an electronic component to be embedded in the insulating layer 12 is not limited to this.

As a modification of the above-described embodiment, the conductor layer C0, conductor layer C4, insulating layer 11, and insulating layer 14 may be formed such that the surface roughness of the surface at which the conductor layer C0 contacts the insulating layer 11 is higher than the surface roughness at which the conductor layer C4 contacts the insulating layer 14. With such a configuration, the adhesion strength between the conductor layer C0 and the insulating layer 11 is higher than the adhesion strength between the conductor layer C4 and the conductor layer 14. For example, assume that a part of the conductor layer C0 is used as an external terminal with an accessing opening formed in the solder resist 31, or an external terminal to be connected to the conductor layer C0 is provided. In this case, it is not necessary to form the structure in which the external terminal is sandwiched by the solder resist 31 provided that the adhesion strength between the conductor layer C0 and the insulating layer 11 is appropriately set. For example, when the surface roughness differs between the front and back sides (both sides in the stacking direction at which the solder resist 32 is formed and at which the solder resist 31 is formed) of the composite electronic component 1, the wiring width, wiring interval, and the like of the conductor pattern to be formed at the front and back sides can be set correspondingly. That is, the lower the roughness of the conductor layer (or insulating layer that contacts the conductor layer) is, the thinner the wiring pattern can be. This makes it possible to, for example, suppress peeling of the conductor layer C4 while making the conductor pattern to be disposed in the conductor layer C4 thinner than the conductor pattern to be disposed in the conductor layer C0.

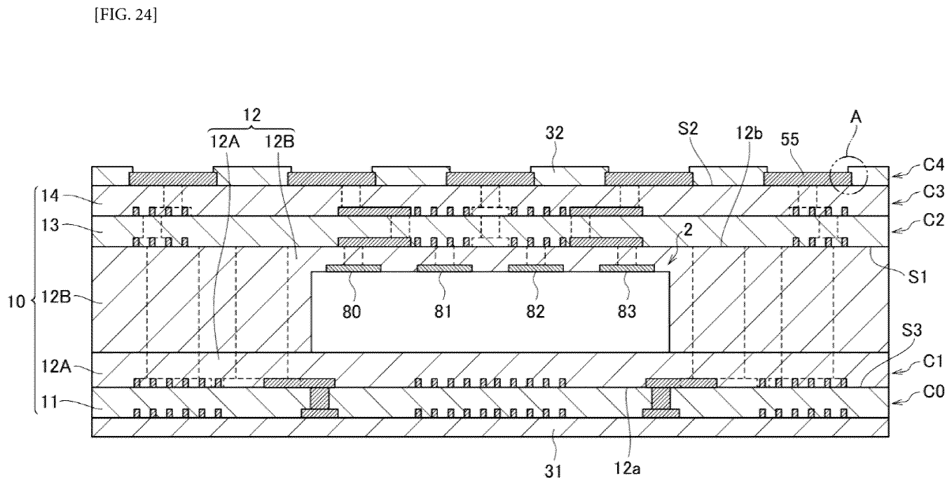

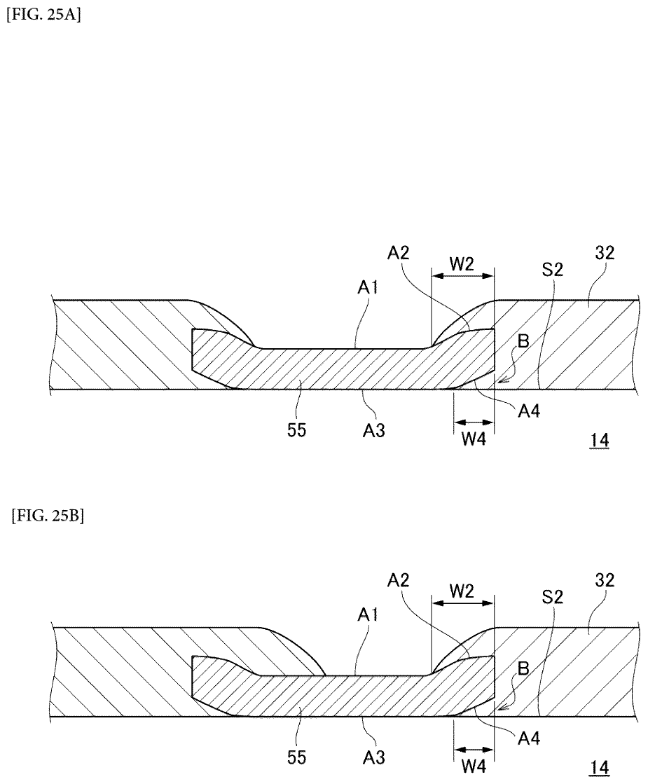

Further, as another modification of the above-described embodiment, the conductor patterns 50 to 57 themselves may be used as the external terminals in place of providing the signal terminals 20 to 27, as illustrated in FIGS. 24 and 25(a). In this case, the thickness of the conductor pattern (e.g., the conductor pattern 55 illustrated in FIG. 25(a)) may be adjusted as needed. The composite electronic component 1 having such a configuration can be manufactured using the same method as that described above. By appropriately adjusting forming conditions in the process of generating the conductor layer C4 and appropriately selecting the copper foil used as the conductor layer C4, the thickness of the conductor patterns 50 to 57 can be appropriately adjusted. Although the area A1 is formed at the center area including substantially the center portion of the conductor pattern 55 in the example illustrated in FIG. 25(a), the present invention is not limited to this, and as illustrated in FIG. 25(b), the area Al may be formed at a position shifted from the center portion of the conductor pattern 55.

The technology according to the present disclosure includes the following configuration examples but not limited thereto.

A composite electronic component according to an aspect of the present disclosure includes: a first insulating layer; an electronic component embedded in the first insulating layer; a wiring structure having first and second surfaces positioned opposite to each other and stacked on the first insulating layer such that the first surface and the first insulating layer face each other; a second insulating layer covering the second surface; and an external terminal. The wiring structure has a conductor pattern provided on the second surface. The second insulating layer covers the outer peripheral area of the conductor pattern, excluding part of the upper surface of the conductor pattern and is filled in a clearance formed between the outer peripheral area defined on the lower surface of the conductor pattern and the second surface. Since the outer peripheral portion of the conductor pattern is thus vertically sandwiched by the second insulating layer, peeling of the conductor pattern is suppressed.

In the above composite electronic component, the second insulating layer may be a solder resist. Thus, peeling of the conductor pattern can be prevented by the solder resist.

In the above composite electronic component, the width of the outer peripheral area defined on the upper surface of the conductor pattern and covered with the second insulating layer may be larger than the width of the outer peripheral area defined on the lower surface of the conductor pattern that is covered with the second insulating layer. This can enhance adhesion between the conductor pattern and the second surface.

In the above composite electronic component, the coefficient of thermal expansion of a third insulating layer constituting the wiring structure may be lower than the coefficient of thermal expansion of the first insulating layer. Thus, deformation of the first insulating layer can be suppressed by the third insulating layer.

In the above composite electronic component, the wiring structure may include a first conductor layer having the conductor pattern and at least one second conductor layer positioned between the first conductor layer and the first insulating layer, and the pattern thickness of the first conductor layer may be larger than the pattern thickness of the second conductor layer. This can further reduce damage to the conductor pattern.

The above composite electronic component may further include a fourth insulating layer having third and fourth surfaces positioned opposite to each other, the first insulating layer may be stacked between the wiring structure and the fourth insulating layer such that the third surface and the first insulating layer face each other, a third conductor layer may be formed on the fourth surface, and the surface roughness of the first conductor layer contacting the second surface may be lower than the surface roughness of the third conductor layer contacting the fourth surface. This can reduce an electrical resistance of the first conductor layer.

This application claims the benefit of Japanese Patent Application No. 2023-022439, filed on Feb. 16, 2023, the entire disclosure of which is incorporated by reference herein.

### REFERENCE SIGNS LIST

1 Composite electronic component
2 ESD protection component (electronic component)
10 element body
11-14, 12A, 12B insulating layer
12a, 12b surface of insulating layer
20-27 signal terminal
28, 29 ground terminal
31, 32 solder resist
41-48 coil pattern
50-59 conductor pattern
60, 61, 63-66, 68 conductor pattern
70-76 conductor pattern
80-87 terminal electrode
91, 93, 94, 97 conductor pattern
100-107, 110-118, 120-127, 130-137, 141, 143, 144, 147 via conductor
200 carrier-attached copper foil
201 resist pattern
202 via
203 seed layer
204 resist pattern
A1, A3 area
A2, A4 outer peripheral area
B clearance
C0-C4 conductor layer
CMF1-CMF4 common mode filter
G1, G2 gap
GP ground pattern
S1-S4 surface

1. A composite electronic component comprising:
a first insulating layer;
an electronic component embedded in the first insulating layer;
a wiring structure having first and second surfaces positioned opposite to each other and stacked on the first insulating layer suc
h that the first surface and the first insulating layer face each other; and
a second insulating layer covering the second surface,
wherein the wiring structure has a conductor pattern provided on the second surface, and
wherein the second insulating layer covers an outer peripheral area of the conductor pattern, excluding part of an upper surface of the conductor pattern and is filled in a clearance formed between an outer peripheral area defined on a lower surface of the conductor pattern and the second surface.

2. The composite electronic component as claimed in claim 1, wherein the second insulating layer is a solder resist.

3. The composite electronic component as claimed in claim 1, wherein a width of the outer peripheral area defined on the upper surface of the conductor pattern and covered with the second insulating layer is larger than a width of the outer peripheral area defined on the lower surface of the conductor pattern that is covered with the second insulating layer.

4. The composite electronic component as claimed in claim 1, wherein a coefficient of thermal expansion of a third insulating layer constituting the wiring structure is lower than a coefficient of thermal expansion of the first insulating layer.

5. The composite electronic component as claimed in claim 1,
wherein the wiring structure includes a first conductor layer having the conductor pattern and at least one second conductor layer positioned between the first conductor layer and the first insulating layer, and
wherein a pattern thickness of the first conductor layer is larger than a pattern thickness of the second conductor layer.

6. The composite electronic component as claimed in claim 5, further comprising a fourth insulating layer having third and fourth surfaces positioned opposite to each other,
wherein the first insulating layer is stacked between the wiring structure and the fourth insulating layer such that the third surface and the first insulating layer face each other,
wherein a third conductor layer is formed on the fourth surface, and
wherein a surface roughness of the first conductor layer contacting the second surface is lower than a surface roughness of the third conductor layer contacting the fourth surface.
